(19) United States
(12) Patent Application Publication
(10) Pub. No.: US 2012/0018773 A1
(43) Pub. Date: Jan. 26, 2012

(54) ALTERNATING-CURRENT LIGHT EMITTING DIODE STRUCTURE WITH OVERLOAD PROTECTION

(75) Inventors: Jing-Yi Chen, Hsinchu County (TW); Shih-Yi Wen, Hsinchu County (TW); Ching-Jen Pan, Hsinchu County (TW); Ming-Hung Chen, Hsinchu County (TW)

(73) Assignee: Helio Optoelectronics Corporation, Taiwan (CN)

(21) Appl. No.: 13/258,627

(22) PCT Filed: Apr. 7, 2009
(86) PCT No.: PCT/CN09/00378

§ 371 Date: Sep. 22, 2011

(51) Int. Cl. H01L 33/64

(52) U.S. Cl. 257/99; 257/E33.075

(57) ABSTRACT

The present invention relates to an alternating current (AC) light emitting diode (LED) structure with overload protection, which comprises an AC LED, a heat dissipating unit and an overload protecting unit. The AC LED is thermally connected with the heat dissipating unit, and the overload protecting unit is connected in series between the AC LED and a power source. Thus, when an overload current is inputted to the AC LED structure, the temperature of the overload protecting unit will rise to disconnect the AC LED from the power source. In this way, an open-circuit status can be produced timely in the AC LED structure to block the power input into the AC LED for purpose of protection against overload.

### CROSS-REFERENCE TO RELATED APPLICATIONS

This is a National Stage Application of International Patent Application No. PCT/CN 2009/000378, with an international filing date of Apr. 7, 2009. The content of the specification is incorporated herein by reference.

### BACKGROUND OF THE INVENTION

1. Technical Field

The present invention relates to an alternating-current (AC) light emitting diode (LED) structure, and more particularly, to an AC LED structure with overload protection.

2. Description of Related Art

As a kind of cold light source having desirable physical properties, light emitting diodes (LEDs) can provide a high luminance and, particularly, have a service life as long as hundreds of thousands of hours. As compared to conventional light sources, the LEDs can be driven by a small current while still providing an equal amount of light, so the power consumption thereof is extremely low. Besides, the LEDs have a wide application scope because of the various varieties and different colors thereof.

However, an LED can only be driven by a direct-current (DC) power source, so a control circuit for converting an alternating current into a direct current and a voltage-drop element must be additionally provided in an LED lamp in order for the LED lamp to operate normally with the alternating-current (AC) utility power. This not only increases the manufacturing cost of the LED lamp, but also prolongs the light-up time of the LED lamp.

Accordingly, AC LEDs that can be driven by an AC power source directly have been developed in recent years. Such an AC LED consists of a plurality of DC LEDs connected in series and in parallel with each other. Therefore, to drive one AC LED is actually to drive a plurality of DC LEDs simultaneously, so a relatively large input current is required in order to drive the AC LED. This tends to cause overload of the AC LED. Moreover, non-periodic impulse interferences often arise in the AC power source. Therefore, the AC LED might be damaged if no effective measures are taken to prevent overload of the AC LED.

Obviously, the prior art AC LED still has shortcomings to be overcome in terms of structure and use. In order to solve the problems described above, almost all manufacturers have spared no effort to find a solution. Unfortunately, no applicable design has been proposed so far; also, no applicable structure capable of solving these problems can be found in common products. Accordingly, it is highly desirable in the art to provide a novel AC LED structure with overload protection.

### SUMMARY OF THE INVENTION

An objective of the present invention is to overcome the shortcomings of the prior art AC LED structure by providing a novel AC LED structure with overload protection. The technical problem to be solved is to protect the AC LED by using an overload protecting unit to adjust the power supply in real time when an overload condition takes place in the AC LED.

Another objective of the present invention is to provide a novel AC LED with overload protection. The technical problem to be solved is to prolong the service life of the AC LED by using an overload protecting unit to quickly block the power input of the AC LED so as to prevent damage caused by an overload current to the AC LED.

The objectives and the technical problems are solved through the following technical solutions. An AC LED structure with overload protection according to the present invention comprises: at least one AC LED; at least one heat dissipating unit, being adapted to support and thermally connected to the AC LED; and at least one overload protecting unit connected in series between the AC LED and a power source.

The objectives and the technical problems may also be solved through the following technical means.

In the AC LED structure with overload protection described above, a distance between the overload protecting unit and the AC LED is smaller than 3 centimeters (cm).

The AC LED structure with overload protection described above further comprises a heat conducting layer disposed between the AC LED and the heat dissipating unit.

In the AC LED structure with overload protection described above, the heat conducting layer is a polymer dielectric layer.

In the AC LED structure with overload protection described above, the overload protecting unit is a conductive spring leaf.

In the AC LED structure with overload protection described above, the overload protecting unit comprises: a conductive spring leaf, being electrically connected to the AC LED and the power source; and a micro-electro-mechanical unit joined to the conductive spring leaf.

The AC LED structure with overload protection described above further comprises: a first electrode, being electrically connected to the AC LED and the power source; and a second electrode, being electrically connected to the overload protecting unit and the power source.

In the AC LED structure with overload protection described above, the first electrode and the second electrode are disposed on a surface of the heat conducting layer.

In the AC LED structure with overload protection described above, the overload protecting unit is a temperature controlling unit.

In the AC LED structure with overload protection described above, the temperature controlling unit comprises: a first conductive layer; a temperature detecting layer, being disposed on the first conductive layer; and a second conductive layer, being disposed on the temperature detecting layer and electrically connected to the AC LED.

In the AC LED structure with overload protection described above, the second conductive layer is electrically connected to the second electrode.

In the AC LED structure with overload protection described above, the second conductive layer comprises: a third conductive layer electrically connected to the AC LED; and a fourth conductive layer, being electrically separated from the third conductive layer and electrically connected to the second electrode.

In the AC LED structure with overload protection described above, when the AC LED is connected to the power source, the temperature controlling unit has a temperature lower than a triggering temperature of positive temperature coefficient characteristics.

In the AC LED structure with overload protection described above, the temperature detecting layer comprises a crystalline polymer material and a conductive material.

In the AC LED structure with overload protection described above, the crystalline polymer material has a melting point of 80° C.˜183° C.

The present invention has significant advantages and benefits as compared to the prior art. With the aforesaid technical solutions, the AC LED structure with overload protection of the present invention at least has the following advantages and benefits:

1. the present invention can protect the AC LED by using the overload protecting unit to adjust the current flowing through the AC LED when an overload current arises; and

2. The present invention can protect the AC LED from being damaged by the overload current so as to prolong the service life of the AC LED.

What described above is only a summary of the present invention. In order for those skilled in the art to understand the technical means of the present invention more clearly so that they can practice the present invention according to the disclosure of the specification and in order to make the aforesaid and other objectives, features and advantages of the present invention more apparent, the present invention will be detailed hereinafter with reference to preferred embodiments thereof.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 is a first schematic view of an embodiment of an AC LED structure with overload protection according to the present invention;

FIG. 2 is a second schematic view of an embodiment of an AC LED structure with overload protection according to the present invention;

FIG. 3 is a third schematic view of an embodiment of the AC LED structure with overload protection according to the present invention;

FIG. 4 is a fourth schematic view of an embodiment of the AC LED structure with overload protection according to the present invention;

FIG. 5 is a schematic view illustrating a resistance as a function of a temperature of a positive-temperature-coefficient material; and

FIG. 6 is a schematic view illustrating an application of the AC LED structure with overload protection according to the present invention.

### DETAILED DESCRIPTION OF THE INVENTION

To further describe the technical means adopted by the present invention to achieve the objectives thereof as well as the efficacy, implementations, structures, features and efficacy of an alternating-current (AC) light emitting diode (LED) structure according to the present invention will be detailed with reference to the attached drawings and preferred embodiments hereinafter.

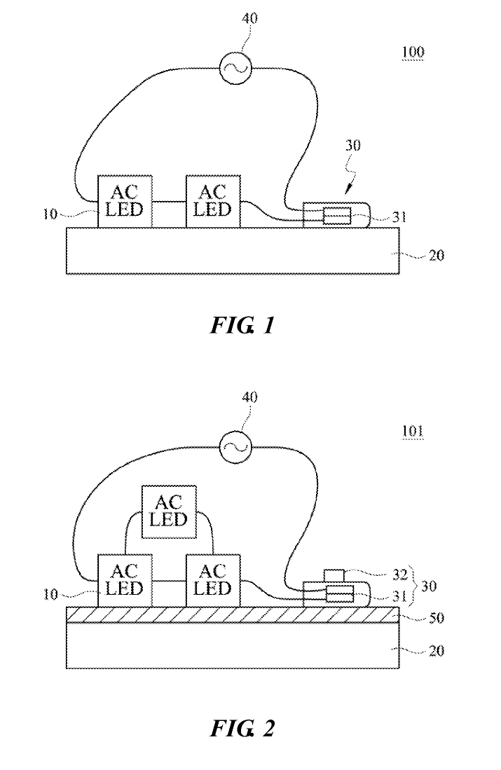

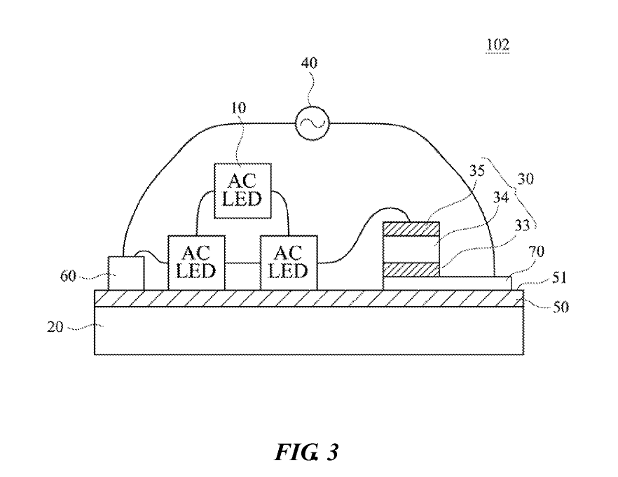

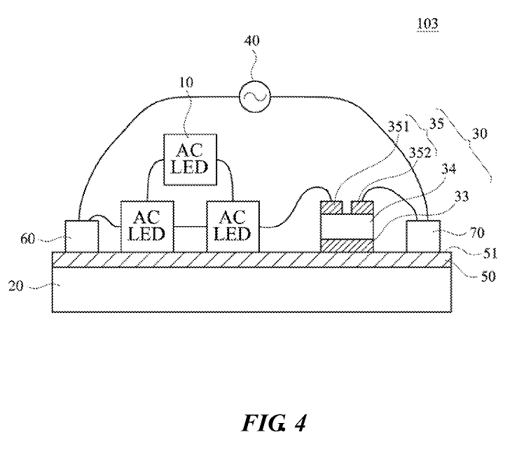

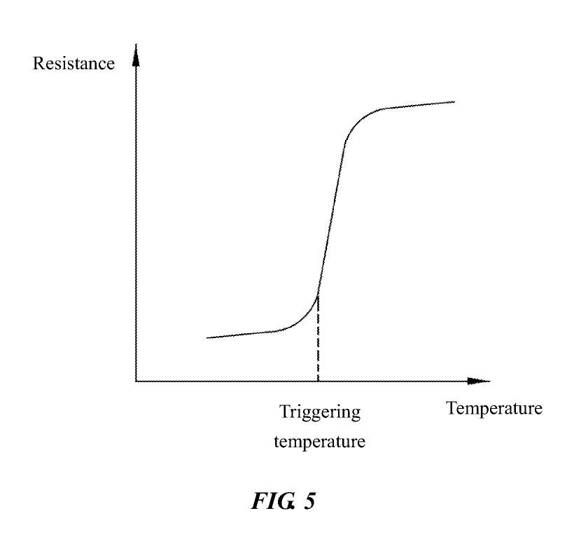

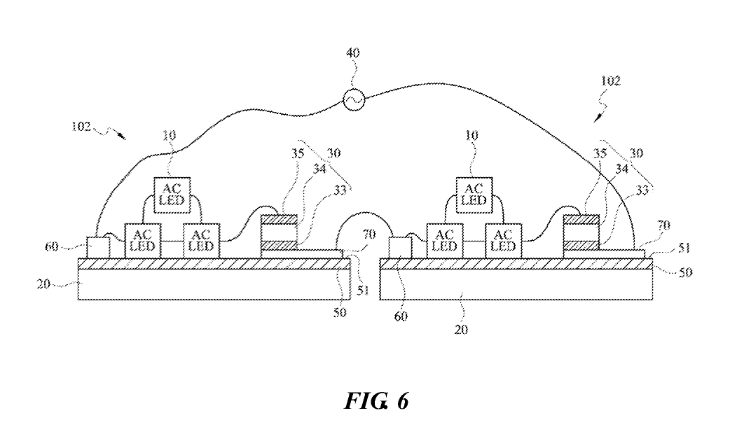

FIG. 1 is a first schematic view of an embodiment of an AC LED structure with overload protection according to the present invention. FIG. 2 is a second schematic view of an embodiment of an AC LED structure with overload protection according to the present invention. FIG. 3 is a third schematic view of an embodiment of the AC LED structure with overload protection according to the present invention. FIG. 4 is a fourth schematic view of an embodiment of the AC LED structure with overload protection according to the present invention. FIG. 5 is a schematic view illustrating a resistance as a function of a temperature of a positive-temperature-coefficient material. FIG. 6 is a schematic view illustrating an application of the AC LED structure with overload protection according to the present invention.

As shown in FIG. 1, the embodiment of the present invention is an AC LED structure 100 with overload protection, which comprises: at least one AC LED 10; at least one heat dissipating unit 20; and at least one overload protecting unit 30. For ease of description, a current higher than a maximum current that the AC LED 10 can withstand is defined as an overload current in this specification.

As shown in FIG. 1 and FIG. 2, the AC LED 10 can be driven by an AC utility power source 40 directly to emit light, so no additional power transformation and rectification devices are needed. Further, different numbers of AC LEDs 10 may be used optionally in the AC LED structure 100 with overload protection to meet every lighting demand, for example, two or three AC LEDs 10.

As shown in FIG. 1, the heat dissipating unit 20 is adapted to support and thermally connected to each of the AC LEDs 10. The heat dissipating unit 20 may be made of a material having a high coefficient of thermal conductivity such as copper (Cu), aluminum (Al), ceramics or the like so that heat generated by the AC LEDs 10 during operation can be dissipated effectively by the heat dissipating unit 20.

However, when the heat dissipating unit 20 expands as being heated, the difference in the coefficient of thermal expansion between the heat dissipating unit 20 and the AC LEDs 10 will result in a force that might damage the AC LEDs 100.

Therefore, as shown in FIG. 2, the AC LED structure 101 may be further provided with a heat conducting layer 50 disposed between the AC LEDs 10 and the heat dissipating unit 20. The heat conducting layer 50 may be made of a dielectric polymer material that has a desirable coefficient of thermal expansion and a desirable coefficient of thermal conductivity; thereby, apart from acting as a buffering layer between the AC LEDs 10 and the heat dissipating unit 20 when the heat dissipating unit 20 expands as being heated, the heat conducting layer 50 can also help to transfer the heat generated by the AC LED 10 to the heat dissipating unit 20.

As shown in FIG. 1 and FIG. 2, the overload protecting unit 30 is connected in series between the AC LEDs 10 and the AC power source 40. Thus, the overload protecting unit 30 can control a magnitude of the current flowing through the AC LEDs 10 to prevent overload of the AC LEDs 10. How the overload protecting unit 30 operates will be described later.

As shown in FIG. 1, the overload protecting unit 30 may be a conductive spring leaf 31 electrically connected to the AC LEDs 10 and the AC power source 40, and conductive spring leaves 31 of different specifications may trip off at different temperatures. In case an overload condition arises in the AC LEDs 10, the temperature of the AC LEDs 10 will rise continuously to cause the temperature of the heat dissipating unit 20 to rise as well. Consequently, the conductive spring leaf 31 on the heat dissipating unit 20 begins to be heated. Once the temperature of the conductive spring leaf 31 rises to a tripping temperature, the conductive spring leaf 31 will trip off to disconnect the AC LEDs 10 from the AC power source 40. It is not until the temperature of the AC LEDs 10 falls to cause a corresponding fall in the temperature of the heat dissipating unit 20 that the temperature of the conductive spring leaf 31 falls below the tripping temperature. Then, the conductive spring leaf 31 automatically resumes the original state so that the AC power source 40 can resume supplying power to the AC LEDs 10.

Besides, the overload current flowing through the conductive spring leaf 31 also causes the temperature of the conductive spring leaf 31 to rise continuously, and once the temperature of the conductive spring leaf 31 rises to the tripping temperature, the conductive spring leaf 31 will also trip off. Therefore, the conductive spring leaf 31 can be heated by the heating dissipating unit 20 and directly by the overload current simultaneously so as to provide more complete overload protection.

As shown in FIG. 2, the overload protecting unit 30 may also comprise a conductive spring leaf 31 and a micro-electro-mechanical unit 32. By using the micro-electro-mechanical unit 32 and the conductive spring leaf 31 in combination and using the micro-electro-mechanical unit 32 to sense a temperature around the conductive spring leaf 31 more accurately, the conductive spring leaf 31 can trip off or be reset at appropriate temperatures so that the overload protecting unit 30 can function more properly.

As shown in FIG. 3, the AC LED structure 102 may further comprise a first electrode 60 and a second electrode 70. The first electrode 60 is electrically connected to the AC LEDs 10 and the AC power source 40, and the second electrode 70 is electrically connected to the overload protecting unit 30 and the AC power source 40. Thus, through disposition of the first electrode 60 and the second electrode 70, a plurality of AC LED structures 102 can be connected in series (as shown in FIG. 6) or in parallel to satisfy demands in different applications.

As shown in FIG. 3 and FIG. 4, the first electrode 60 and the second electrode 70 may be disposed on a surface 51 of the heat conducting layer 50, and the overload protecting unit 30 of each of the AC LED structures 102, 103 may be a temperature controlling unit. The temperature controlling unit may comprise a first conductive layer 33, a temperature detecting layer 34, and a second conductive layer 35.

As shown in FIG. 3, the first conductive layer 33 may be disposed on and electrically connected to the second electrode 70, the temperature detecting layer 34 may be disposed on the first conductive layer 33, and the second conductive layer 35 is in turn disposed on the temperature detecting layer 34 and electrically connected to the AC LEDs 10.

Further, the temperature detecting layer 34 may comprise a crystalline polymer material and a conductive material. The crystalline polymer material may have a melting point of 80° C.˜183° C., and the conductive material may be carbon black, graphite, or the like conductive material. Additionally, the temperature detecting layer 34 may have positive temperature coefficient characteristics; i.e., as shown in FIG. 5, if the temperature of the temperature detecting layer 34 exceeds a triggering temperature, the resistance of the temperature detecting layer 34 will increase quickly within a short time to disconnect the second conductive layer 35 from the first conductive layer 33.

When the AC LEDs 10 initially connects to the AC power source 40, the temperature of the temperature controlling unit is lower than a triggering temperature of the positive temperature coefficient characteristics, and at this point, the second conductive layer 35 and the first conductive layer 33 are electrically connected to each other. Then, in case an overload condition arises in the AC LEDs 10, the temperatures of the AC LEDs 10, the heat conducting layer 50 and the heat dissipating unit 20 will rise continuously to cause a corresponding temperature rise of the temperature detecting layer 34. Consequently, the resistance value of the temperature detecting layer 34 will increase gradually.

Once the temperature of the temperature detecting layer 34 exceeds the triggering temperature, the second conductive layer 35 and the first conductive layer 33 are disconnected from each other. This state is kept until the temperature of the temperature detecting layer 34 decreases gradually with that of the AC LEDs 10. Then, the resistance value of the temperature detecting layer 34 begins to decrease gradually to cause gradual increase in magnitude of the current between the second conductive layer 35 and the first conductive layer 33. In this way, the magnitude of the current flowing through the AC LEDs 10 can be adjusted for purpose of overload protection of the AC LED structure 102.

As shown in FIG. 4, the second electrode 70 may also be electrically connected via the second conductive layer 35. In this case, the second conductive layer 35 of the overload protecting unit 30 may comprise a third conductive layer 351 and a fourth conductive layer 352. The third conductive layer 351 and the fourth conductive layer 352 are electrically separated from each other, the third conductive layer 351 is electrically connected to the AC LCDs 10, and the fourth conductive layer 352 is electrically connected to the second electrode 70. Because the second electrode 70 can be electrically connected via the fourth conductive layer 352, the first conductive layer 33 of the overload protecting unit 30 may be disposed on the surface 51 of the heat conducting layer 50 directly or even be attached onto the AC LEDs 10 (not shown) directly to detect the temperature of the AC LEDs 10 from a closer distance.

In the above descriptions, each overload protecting unit 30 has a distance of smaller than 3 centimeters (cm) from the AC LEDs 10 so that heat can be transferred effectively from each of the AC LEDs 10 or from the heat dissipating unit 20 to the overload protecting unit 30. Also through disposition of the heat conducting layer 50, the heat can be transferred more quickly from the AC LEDs 10 to the overload protecting unit 30.

In case of being a temperature controlling unit, the overload protecting unit 30 can control light intensity of each of the AC LEDs 10 by adjusting a magnitude of the current flowing through the AC LEDs 10. In this way, the AC LED structures 102, 103 can be designed as lamps capable of automatically adjusting the light intensity, thus extending the application scope of the AC LED structures 102, 103.

What described above are only preferred embodiments of the present invention but are not intended to limit the present invention in any way. Although the present invention has been disclosed with reference to the preferred embodiments, it is not merely limited thereto. Rather, slight alterations or modifications may be made by those skilled in the art based on the technical disclosure without departing from the scope of the present invention, and all these alterations and modifications shall still be covered in the scope of the present invention.

What is claimed is:

1. An alternating current (AC) light emitting diode (LED) structure with overload protection, comprising:
at least one AC LED;
at least one heat dissipating unit, being adapted to support and thermally connected to the AC LED; and
at least one overload protecting unit connected in series between the AC LED and a power source.

2. The AC LED structure of claim 1, wherein a distance between the overload protecting unit and the AC LED is smaller than 3 centimeters (cm).

3. The AC LED structure of claim 1, further comprising a heat conducting layer disposed between the AC LED and the heat dissipating unit.

4. The AC LED structure of claim 3, wherein the heat conducting layer is a polymer dielectric layer.

5. The AC LED structure of claim 1, wherein the overload protecting unit is a conductive spring leaf.

6. The AC LED structure of claim 1, wherein the overload protecting unit comprises: a conductive spring leaf, being electrically connected to the AC LED and the power source; and a micro-electro-mechanical unit joined to the conductive spring leaf.

7. The AC LED structure of claim 3, further comprising: a first electrode, being electrically connected to the AC LED and the power source; and a second electrode, being electrically connected to the overload protecting unit and the power source.

8. The AC LED structure of claim 7, wherein the first electrode and the second electrode are disposed on a surface of the heat conducting layer.

9. The AC LED structure of claim 7, wherein the overload protecting unit is a temperature controlling unit.

10. The AC LED structure of claim 9, wherein the temperature controlling unit comprises: a first conductive layer; a temperature detecting layer, being disposed on the first conductive layer; and a second conductive layer, being disposed on the temperature detecting layer and electrically connected to the AC LED.

11. The AC LED structure of claim 10, wherein the second conductive layer is electrically connected to the second electrode.

12. The AC LED structure of claim 10, wherein the second conductive layer comprises: a third conductive layer electrically connected to the AC LED; and a fourth conductive layer, being electrically separated from the third conductive layer and electrically connected to the second electrode.

13. The AC LED structure of claim 10, wherein when the AC LED is connected to the power source, the temperature controlling unit has a temperature lower than a triggering temperature of positive temperature coefficient characteristics.

14. The AC LED structure of claim 10, wherein the temperature detecting layer comprises a crystalline polymer material and a conductive material.

15. The AC LED structure of claim 14, wherein the crystalline polymer material has a melting point of 80° C.˜183° C.
